(19) United States
(12) Patent Application Publication
(10) Pub. No.: US 2014/0009111 A1
(43) Pub. Date: Jan. 9, 2014

(54) CHARGER, ELECTRONIC APPARATUS, AND STORAGE CASE

(71) Applicant: Kabushiki Kaisha Toshiba, Tokyo (JP)

(72) Inventors: Terumasa Nagasaki, Ome-shi (JP); Nobuyasu Tajima, Chigasaki-shi (JP)

(73) Assignee: Kabushiki Kaisha Toshiba, Tokyo (JP)

(21) Appl. No.: 14/024,503

(22) Filed: Sep. 11, 2013

Related U.S. Application Data
(63) Continuation of application No. 12/968,137, filed on Dec. 14, 2010.

(30) Foreign Application Priority Data
Feb. 19, 2010 (JP) 2010-035032

(51) Int. Cl. H05K 7/20; H02J 7/02

(52) U.S. Cl. CPC H05K 7/20127; H02J 7/025
USPC 320/108; 320/107

(57) ABSTRACT

According to one embodiment, configured to be charged by a charger, an electronic apparatus comprises a first housing, a display device, a power reception unit and a second housing. Arranged in the first housing, the display device comprises a display screen. The power reception unit is arranged at the first housing in a position overlapping the display device on a side opposite to the display screen and in a position eccentric from a center of the display device, and configured to receive an electricity transmitted from a power transmission unit of the charger with the first housing standing on an exterior setting surface. The second housing is configured to support the first housing with standing on the exterior setting surface, and an input device on the second housing.

### CROSS-REFERENCE TO RELATED APPLICATIONS

This application is a continuation of U.S. patent application Ser. No. 12/968,137, filed Dec. 14, 2010, which is based upon and claims the benefit of priority from Japanese Patent Application No. 2010-035032, filed Feb. 19, 2010; the entire contents of both of which are incorporated herein by reference.

### FIELD

Embodiments described herein relate generally to a non-contact charger for charging an electronic apparatus with electricity, an electronic apparatus chargeable by the charger, and a storage case for accommodating the charger and electronic apparatus.

### BACKGROUND

Presently, rechargeable batteries, such as nickel-hydrogen and lithium-ion batteries, are the main energy sources for portable electronic apparatuses, such as notebook PCs, mobile terminals, gaming devices, PDAs, etc. A novel charger for charging the rechargeable batteries of these electronic apparatuses has recently been proposed in which energy is transmitted in a non-contact manner (e.g., Jpn. Pat. Appln. KOKAI Publication No. 2006-320047). This charger generates electricity by supplying fuel from a fuel cartridge to a fuel cell and transmits the generated electricity to a mobile device by means of a transmission coil.

Air needs to be supplied in generating electricity by a fuel cell, and water vapor and carbon dioxide are discharged as the electricity is generated. The above-described charger cannot overcome the inherent problems of a fuel battery, including such air supply and discharging of water vapor and carbon dioxide. Thus, the air supply may be insufficient or the discharged water vapor and carbon dioxide may affect the performance of the electronic apparatuses.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is an exemplary perspective view, partially in section, of a non-contact charger according to an embodiment;

FIG. 2 is an exemplary side view showing the charger and a notebook PC to be charged by the charger;

FIG. 3 is an exemplary perspective view showing the notebook PC;

FIG. 4 is an exemplary front view showing a storage case according to the embodiment for accommodating the charger and notebook PC; and

FIG. 5 is a sectional view of the storage case taken along line V-V of FIG. 4.

### DETAILED DESCRIPTION

Various embodiments will be described hereinafter with reference to the accompanying drawings.

In general, according to one embodiment, a charger comprises a fuel cell configured to generate electricity; an intake/exhaust unit configured to supply air to the fuel cell and discharge an emission from the fuel cell; a fuel tank configured to supply fuel to the fuel cell; and a power transmission unit configured to transmit the electricity generated in the fuel cell in a non-contact manner. The power transmission unit and the intake/exhaust unit are oriented in different directions.

A charger, electronic apparatus, and storage case according to an embodiment of the invention will now be described in detail with reference to the accompanying drawings.

As shown in FIG. 1, a non-contact charger 10 using a fuel battery comprises a housing 12 in the form of, for example, a rectangular box. The charger 10 further comprises a fuel tank 14 in which fuel is stored, fuel cell module 16 configured to generate electricity, secondary battery 18, power transmission unit 20, and power circuit 22, which are arranged in the housing 12.

The fuel cell module 16 is constructed as, for example, a passive DMFC. A plurality of single cells constitute the cell module 16. Each of the single cells comprises a membrane electrode assembly (MEA), which integrally comprises a cathode (air electrode), anode (fuel electrode), and polymer electrolyte membrane sandwiched between the cathode and anode. The fuel and air supplied to each single cell electrochemically react with each other in the electrolyte membrane between the anode and cathode, thereby generating electricity between the anode and cathode. With the progress of the electrochemical reaction, carbon dioxide and water vapor are produced as reaction by-products on the anode and cathode sides, respectively, of the single cell.

The charger 10 comprises an intake/exhaust unit 24. The intake/exhaust unit 24 takes in and supplies external air for electricity generation to the fuel cell module 16, and also externally discharges the water vapor and carbon dioxide (in the case of the DMFC) produced by the electricity generation in the cell module 16. The intake/exhaust unit 24 is exposed in and opposed to one principal surface 12a of the housing 12.

The power transmission unit 20 comprises, for example, a power transmission coil (a primary-side coil, not shown), which is exposed in and opposed to one surface of the housing 12. Specifically, the power transmission unit 20 is provided on the a surface different from the principal surface 12a on which the intake/exhaust unit 24 is disposed, that is, on a principal surface 12b opposite the principal surface 12a. Thus, the intake/exhaust unit 24 and power transmission unit 20 are oriented back to back or oppositely.

The fuel tank 14 is connected to the fuel cell module 16 and supplies fuel, e.g., an aqueous methanol solution, to the cell module 16. The fuel tank 14 may be constructed as a cartridge removably attached to the housing 12. Within the housing 12, the fuel tank 14 is located vertically above the intake/exhaust unit 24 and power transmission unit 20.

The fuel cell module 16, secondary battery 18, and power transmission unit 20 are electrically connected to the power circuit 22, which controls the electricity generation in the cell module 16, power transmission, and charging/discharging of the secondary battery. The secondary battery 18 is used to compensate for deficiency of electricity generated in the cell module 16 caused if the transmitted power suddenly changes.

DC power generated in the fuel cell module 16 is converted to AC power by the power circuit 22 and delivered to the power transmission unit 20. The AC power is wirelessly transmitted to an apparatus to be charged by the power transmission coil of the power transmission unit 20.

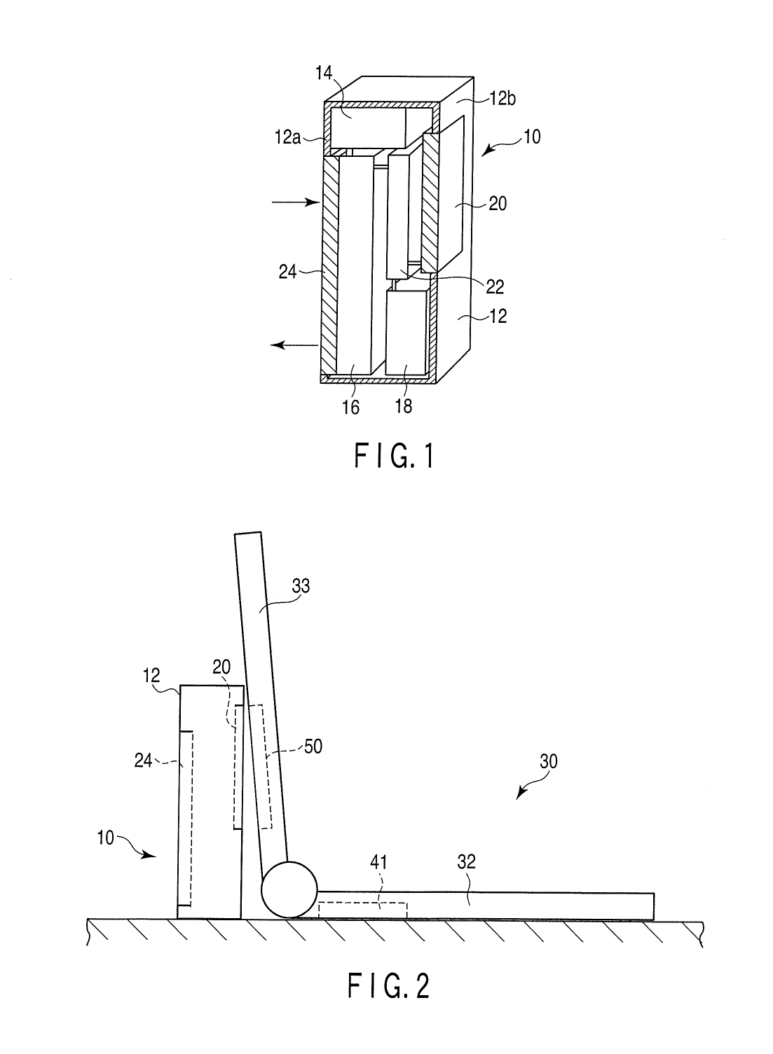

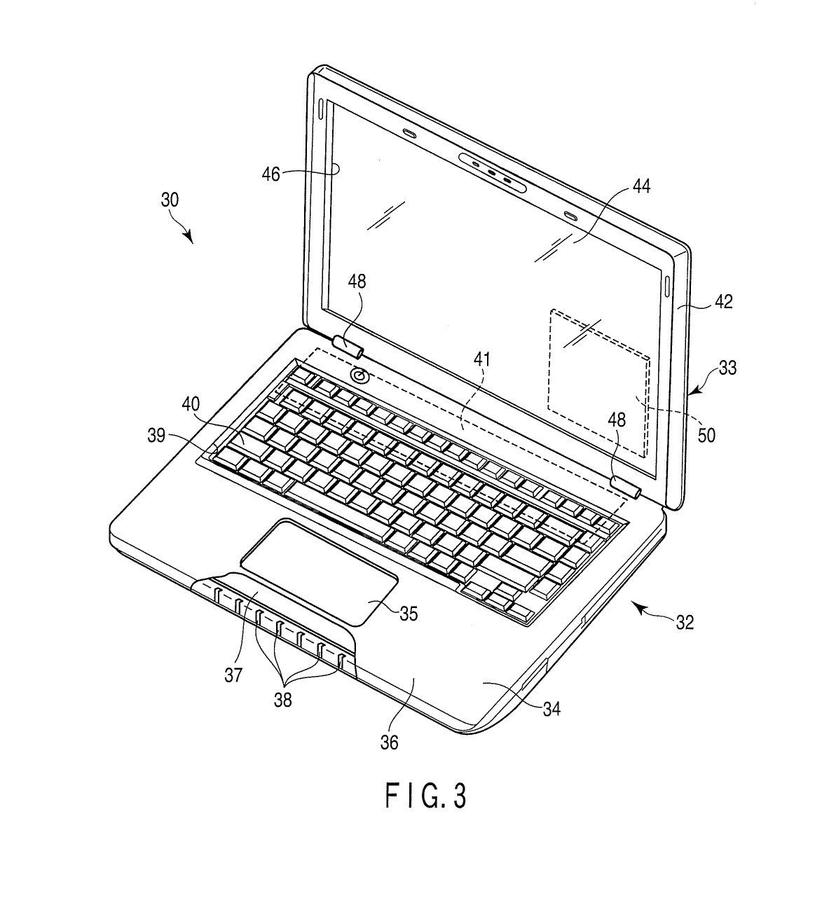

FIGS. 2 and 3 show a notebook computer (notebook PC) 30 according to the embodiment as the electronic apparatus to be charged by the charger 10. The notebook PC 30 comprises an apparatus main body 32 and a display unit 33 supported by the main body 32. The main body 32 comprises a flat rectangular housing 34 of, for example, a synthetic resin.

A palm-rest portion 36 is formed on the upper surface of the housing 34, and a touchpad 35 and click button 37 are arranged substantially on the center of the palm-rest portion. A plurality of LEDs 38 indicative of operation modes of the notebook PC 30 are arranged on the front end portion of the upper surface of the housing 34. In the upper surface of the housing 34, a rectangular opening 39 is formed behind the palm-rest portion 36. A keyboard 40 for use as an input device is disposed in the opening 39. The input device is not limited to a keyboard and may alternatively be a touch panel or the like.

A main circuit board, CPU, memory, etc., which are not shown, are arranged in the housing 34. Further, a secondary battery 41 that functions as a rechargeable battery is removably attached to the bottom side of the rear part of the housing 34.

The display unit 33 comprises a housing 42 in the form of a flat rectangular box and a liquid-crystal display panel 44, which is contained in the housing 42 and functions as a display device. The display screen of the display panel 44 is externally exposed through a display window 46 in the housing 42. The display unit 33 is pivotably supported on the rear end portion of the housing 34 by a pair of hinges 48 on the rear end portion of the apparatus main body 32. Thus, the display unit 33 is pivotable between a closed position in which it is leveled so as to cover the keyboard 40 from above and an illustrated open position in which it stands behind the keyboard.

Within the display unit 33, a power reception unit 50 is provided on the back side of the display panel 44. The power reception unit 50 comprises, for example, a reception coil (a secondary-side coil), which is electrically connected to a main circuit board and charging control circuit in the apparatus main body 32. The power reception unit 50 receives power transmitted from the charger 10 and supplies it to the charging control circuit.

In charging the secondary battery 41 of the notebook PC 30 by means of the charger 10, the charger 10 is placed on, for example, a desk with the power transmission unit 20 and intake/exhaust unit 24 standing upright, as shown in FIG. 2. The notebook PC 30 is placed on the desk with its display unit 33 open so that the power reception unit 50 on the back side of the display unit 33 is opposed to the power transmission unit 20 of the charger 10. In this state, the charger 10 is activated to generate electricity in the fuel cell module 16, and generated power is transmitted from the power transmission unit 20 to the power reception unit 50 of the notebook PC 30 in a non-contact manner. Specifically, the DC power generated in the cell module 16 is converted to AC power by the power circuit 22 and delivered to the power transmission unit 20 and input to the power transmission coil. The AC power is converted by the power transmission coil to magnetic flux, which is input to the power reception unit 50. In the power reception unit 50 of the notebook PC 30, the power reception coil is excited by the input magnetic flux, and the AC power is output. This AC power is converted to DC power by the power circuit of the PC 30 and further input to the secondary battery 41 through the charging control circuit. Thereupon, the secondary battery 41 is charged.

On the other hand, the intake/exhaust unit 24 of the charger 10 is located on the opposite side to the notebook PC 30. During charging, the external air is introduced through the intake/exhaust unit 24 and supplied to the fuel cell module 16. The by-products of the electricity generation are discharged through the intake/exhaust unit 24 to the opposite side to the notebook PC 30.

According to the charger 10 constructed in this manner, the intake/exhaust unit 24 and power transmission unit 20 are arranged on the opposite faces of the charger. Even when the power transmission unit 20 and power reception unit 50 of the apparatus to be charged are joined together, therefore, the intake/exhaust unit 24 cannot be closed by the apparatus to be charged, so that necessary air for the electricity generation can be reliably introduced. At the same time, the water vapor and carbon dioxide produced by the electricity generation can be discharged away (or oppositely in this case) from the power transmission unit 20, so that the discharged by-products can be prevented from impinging on the apparatus to be charged. According to the charger 10, necessary air for the electricity generation can be secured, and the apparatus to be charged can be protected against the produced water vapor and carbon dioxide. Thus, the reliability of the charger can be improved.

According to the notebook PC constructed in this manner, moreover, the power reception unit 50 is provided on a back portion of the pivotable display unit. Therefore, the charger 10 can be used with the power transmission unit 20 and intake/exhaust unit 24 externally exposed. Accordingly, charging can be performed without causing the intake/exhaust unit 24 of the charger 10 to be closed between the desk and charger or failing to place the PC stably on the desk. Thus, if the power reception unit is located on the bottom side of the PC, the intake/exhaust unit of the charger is inevitably closed between the desk and the main body of the charger when charging is attempted with the PC on the desk. If the face of the charger on which the power transmission unit (intake/exhaust unit) is located is too small relative to the footprint of the PC, furthermore, the charger cannot be stably placed on the desk. According to the present embodiment, the notebook PC can be charged by the charger 10 without causing these problems.

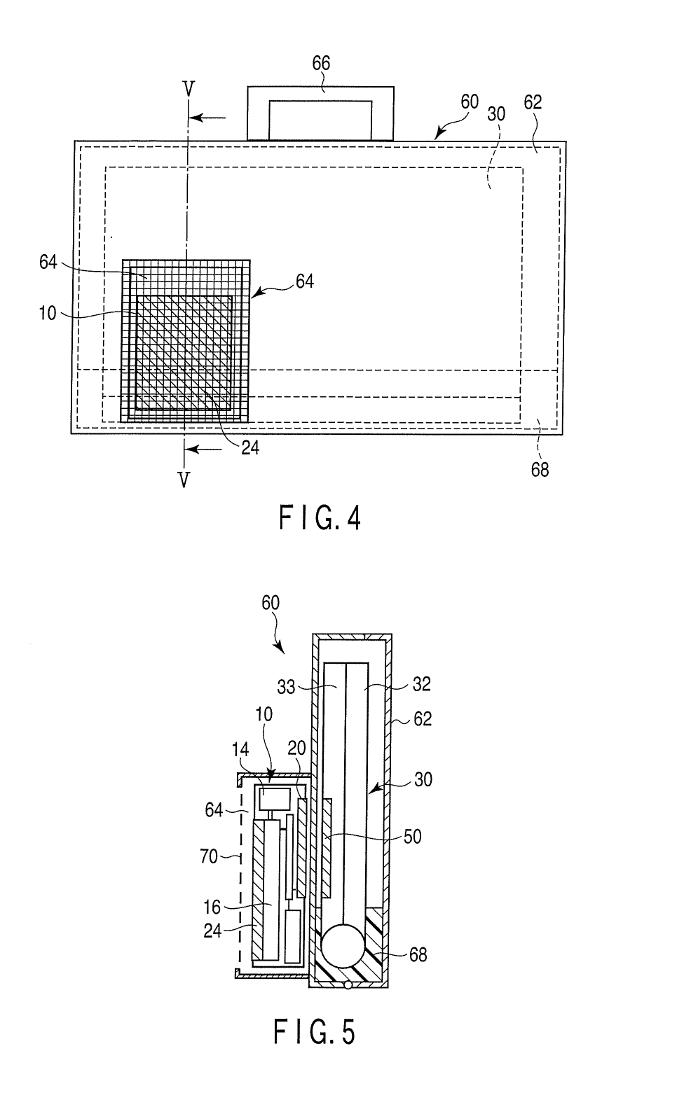

FIGS. 4 and 5 show a storage case 60 that contains the charger 10 and notebook PC 30 as the apparatus to be charged. Since the charger 10 is of the non-contact type, the storage case 60 can spatially separate the apparatus to be charged from the charger 10 while the former is being charged by the latter. Thus, maintenance of ventilation can be reconciled with protection of the apparatus to be charged.

More specifically, the storage case 60 is divided into two storage spaces, a main case 62 and sub-case 64. The main case 62 forms an apparatus storage portion that contains the notebook PC so as to cover its outer periphery. The sub-case 64 forms a charger storage portion that contains the charger 10. The main case 62 is in the form of, for example, a flat rectangular box larger than the PC. The main case 62 is formed of a synthetic resin or other material that has neither electrical nor magnetic shielding properties but has a desired mechanical strength. The main case 62 is openable and closable. Further, a handle 66 is mounted on the outer surface of the main case 62 for better portability.

A positioning member 68 is disposed in the main case 62. The positioning member 68 engages with a part of the notebook PC 30 in the main case 62 and positions and holds the PC in a predetermined position in the main case. In this case, the notebook PC 30 is positioned so that the power reception unit 50 faces the charger storage portion.

The sub-case 64 is secured to one outer face of the main case 62. The sub-case 64 is in the form of a rectangular box slightly larger than the charger 10, and its one principal surface side is opposed to the main case 62. A vent portion 70 for the passage of air is formed in an atmospheric-side surface of the sub-case 64 opposite to the main case 62. The vent portion 70 comprises a large number of vents or meshes as illustrated.

The charger 10 is contained in the sub-case 64 in such a manner that its intake/exhaust unit 24 and power transmission unit 20 face the vent portion 70 and the power reception unit 50 of the electronic apparatus in the main case 62, respectively.

According to the storage case 60 constructed in this manner, the main case 62 is configured to cover the outer periphery of the apparatus to be charged to protect it and can contain the apparatus so that the power reception unit 50 faces the charger storage portion. The sub-case 64 is formed so that its outer (atmospheric-side) surface is meshed to ensure ventilation around the intake/exhaust unit 24 of the charger 10. The charger 10 is contained in the sub-case 64 in such a manner that its intake/exhaust unit 24 and power transmission unit 20 face the meshed surface and the main case 62, respectively. Thus, the power reception unit 50 overlaps the power transmission unit 20 of the charger 10 when the notebook PC is contained in the storage case 60.

The rechargeable battery of the notebook PC 30 can be charged with the PC and charger 10 in the storage case 60. If the charger 10 is activated, air is introduced and fed into the fuel cell module 16 through the vent portion 70 by the intake/exhaust unit 24. The by-products of the electricity generation are externally discharged through the vent portion 70 by the intake/exhaust unit 24. The generated electricity is transmitted from the power transmission unit 20 to the power reception unit 50 of the notebook PC 30 in the main case 62 and so charges the secondary battery of the notebook PC. Such charging can also be achieved when the storage case 60 is being carried.

According to the storage case 60 constructed in this manner, the charger and apparatus storage portions are arranged independently of each other, and the charger storage portion comprises the vent portion. Therefore, maintenance of air supply can be reconciled with protection of the electronic apparatus even when the apparatus is kept in storage or being carried.

According to this arrangement, there may be provided a charger with improved reliability, capable of ensuring sufficient air supply and eliminating the influence of emissions on an apparatus to be charged, an electronic apparatus chargeable by the charger, and a storage case for accommodating the charger and electronic apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

In the embodiments described herein, the intake/exhaust unit of the charger is opposed to the power transmission unit. However, the intake/exhaust unit is only expected to be oriented differently from the power transmission unit. Further, the apparatus to be charged is not limited to a notebook PC and may be any of various other electronic apparatuses, e.g., a mobile terminal, cellphone, recorder, etc. The apparatus storage portion and charger storage portion of the storage case are not limited to the shapes of rectangular boxes and their shapes may be variously changed, if necessary.

What is claimed is:

1. An electronic apparatus configured to be charged by a charger, comprising:
a first housing;
a display device in the first housing and comprising a display screen;
a power reception unit arranged at the first housing in a position overlapping the display device on a side opposite to the display screen and in a position eccentric from a center of the display device, and configured to receive an electricity transmitted from a power transmission unit of the charger with the first housing standing on an exterior setting surface; and
a second housing configured to support the first housing with standing on the exterior setting surface, and an input device on the second housing.

2. The electronic apparatus of claim 1, wherein the power reception unit is in the first housing at a position eccentric from the center of the display device to the exterior setting surface.

3. The electronic apparatus of claim 1, wherein the charger comprises a coil configured to generate magnetic flux, and is configured to input the magnetic flux generated by the coil to another coil in the electronic apparatus so as to transmit electricity to the electronic device.

4. The electronic apparatus of claim 1, wherein the power reception unit comprises a coil configured to receive magnetic flux from the charger to generate electricity, thereby receiving electricity from the charger.

5. The electronic apparatus of claim 1, wherein the charger comprises a first coil configured to generate magnetic flux by electricity, and the power reception unit comprises a second coil configured to face the first coil in non-contact manner and configured to receive magnetic flux from the first coil to generate electricity.

6. The electronic apparatus of claim 1, wherein the second housing is configured to be placed on the exterior surface with the first housing standing upright.

7. An electronic apparatus configured to be charged by a charger, comprising:
a first housing;
a display device in the first housing and comprising a display screen;
a coil arranged at the first housing in a position overlapping the display device on a side opposite to the display screen and in a position eccentric from a center of the display device, and configured to receive magnetic flux generated from the charger in a non-contact manner with the charger to generate electricity in a state wherein the display device stands at an angle across to an exterior setting surface; and
a second housing configured to support the first housing with standing at the angle across to the exterior setting surface, and an input device on the second housing.

8. The electronic apparatus of claim 7, wherein the coil is in the first housing at a position eccentric from the center of the display device to the exterior setting surface.

9. The electronic apparatus of claim 7, wherein the second housing is configured to be placed on the exterior surface with the first housing standing upright.

10. A charger configured to charge an external electronic apparatus, comprising:
a first housing;
a coil arranged in the first housing at a position overlapping a display device on a side opposite to a display screen of the display device and in a position eccentric from a center of the display device in a state wherein the display device connected to the electronic apparatus stands at an angle across to an exterior setting surface, and configured to generate magnetic flux toward the electronic apparatus; and
a second housing configured to support the first housing with standing at the angle across to the exterior setting surface, and an input device on the second housing.

11. The charger of claim 10, wherein the second housing is configured to be placed on the exterior surface with the first housing standing upright.

12. A storage case configured to contain a charger and an electronic apparatus configured to be charged by the charger and including a first housing, a display device in the first housing and comprising a display screen, a coil arranged in a position overlapping the display device on a side opposite to the display screen and in a position eccentric from a center of the display device and configured to receive magnetic flux generated from the charger in a non-contact manner with the charger to generate electricity in a state wherein the display device stands at an angle across to an exterior setting surface, and a second housing configured to support the first housing with standing at the angle across to the exterior setting surface, and an input device on the second housing, the storage case comprising:
an apparatus storage portion configured to contain the electronic apparatus and cover an outer periphery of the electronic apparatus; and
a charger storage portion provided on an outside the apparatus storage portion, comprising a vent portion through which air passes and configured to contain the charger in such a manner that the intake/exhaust unit of the charger and the coil of the charger face the vent portion and the coil of the electronic apparatus in the apparatus storage portion, respectively.

13. The storage case of claim 12, wherein the apparatus storage portion is formed of a material without an electrical shielding property and covers the outer periphery of the electronic apparatus.
